(19) United States
(12) Patent Application Publication
(10) Pub. No.: US 2021/0359113 A1
(43) Pub. Date: Nov. 18, 2021

(54) TRANSISTOR AND MANUFACTURING METHOD THEREOF

(71) Applicant: Powerchip Semiconductor Manufacturing Corporation, Hsinchu (TW)

(72) Inventors: Hung-Kwei Liao, Taoyuan City (TW); Chen-Chiang Liu, Hsinchu County (TW); Yung-Yao Shih, Hsinchu City (TW)

(73) Assignee: Powerchip Semiconductor Manufacturing Corporation, Hsinchu (TW)

(21) Appl. No.: 16/916,044

(22) Filed: Jun. 29, 2020

(30) Foreign Application Priority Data
May 18, 2020 (TW) 109116418

(51) Int. Cl. H01L 29/737; H01L 29/66; H01L 29/10; H01L 29/08; H01L 29/161

(52) U.S. Cl. CPC H01L 29/7371; H01L 29/66242; H01L 29/161; H01L 29/0821; H01L 29/0817; H01L 29/1004

(57) ABSTRACT

Provided are a transistor and a manufacturing method thereof. The transistor includes a substrate, a collector, a base, an emitter and a diffusion barrier layer. The collector is disposed on the substrate. The base is disposed on the collector. The emitter is disposed on the base. The diffusion barrier layer is disposed between the base and the emitter. An upper portion of the base includes a doped layer, and the diffusion barrier layer is disposed on the doped layer. The emitter, the doped layer, and the collector are of a first conductive type, and the rest of the base is of a second conductive type.

### CROSS-REFERENCE TO RELATED APPLICATION

This application claims the priority benefit of Taiwan application serial no. 109116418, filed on May 18, 2020. The entirety of the above-mentioned patent application is hereby incorporated by reference herein and made a part of this specification.

### BACKGROUND

### Technical Field

The present invention relates to a semiconductor device and a manufacturing method thereof, and particularly relates to a transistor and a manufacturing method thereof.

### Description of Related Art

A heterojunction bipolar transistor (HBT) is a kind of bipolar transistor, wherein each of an emitter and a base includes different semiconductor materials to form a heterojunction, that is, a PN junction. Compared with ordinary bipolar transistors, the HBT has better high-frequency signal characteristics and base emission efficiency, so the HBT can be used in signals up to hundreds of GHz, and thus can be widely used.

Generally speaking, in the manufacturing process of the HBT, after the base is formed, the emitter with a different conductive type is formed thereon. Since the emitter is usually formed by in-situ doping, the dopant in the emitter may diffuse into the upper portion of the base. In addition, after the emitter is formed, the subsequent thermal process may also cause the dopant in the emitter to diffuse into the upper portion of the base. To avoid further diffusion of the dopant penetrating through the base, the base w is usually formed with a larger thickness. As a result, the resistance value of the base is increased, and thus the cutoff frequency of the HBT is reduced, which reduces the device performance.

### SUMMARY

The present invention provides a transistor in which the diffusion barrier layer is disposed between the base and the emitter.

The present invention provides a manufacturing method of a transistor, in which a diffusion barrier layer is formed between the base and the emitter.

A transistor of the present invention includes a substrate, a collector, a base, an emitter and a diffusion barrier layer. The collector is disposed on the substrate. The base is disposed on the collector. The emitter is disposed on the base. The diffusion barrier layer is disposed between the base and the emitter. An upper portion of the base includes a doped layer, and the diffusion barrier layer is disposed on the doped layer. The emitter, the doped layer, and the collector are of a first conductive type, and the rest of the base is of a second conductive type.

In an embodiment of the transistor of the present invention, the diffusion barrier layer includes a silicon nitride layer.

In an embodiment of the transistor of the present invention, a thickness of the diffusion barrier layer is between 5 Å and 10 Å.

In an embodiment of the transistor of the present invention, the base includes a SiGe layer, a doped SiCGe layer and the doped layer. The SiGe layer is disposed on the collector.

The doped SiCGe layer is disposed on the SiGe layer. The doped layer is disposed on the doped SiCGe layer.

In an embodiment of the transistor of the present invention, the doped layer is a doped polysilicon layer.

A manufacturing method of a transistor of the present invention includes the following steps. A collector is formed on a substrate. A base is formed on the collector. A diffusion barrier layer is formed on the base. A doped emitter is formed on the diffusion barrier layer, wherein the dopant in the doped emitter penetrates through the diffusion barrier layer and into an upper portion of the base, so that the upper portion of the base is formed to a doped layer. The doped emitter, the doped layer and the collector are of a first conductive type, and the base is of a second conductive type.

In an embodiment of the manufacturing method of the present invention, the diffusion barrier layer includes a silicon nitride layer.

In an embodiment of the manufacturing method of the present invention, a thickness of the diffusion barrier layer is between 5 Å and 10 Å.

In an embodiment of the manufacturing method of the present invention, a forming method of the base includes the following steps. A SiGe layer is formed on the collector. A doped SiCGe layer is formed on the SiGe layer. An undoped layer is formed on the doped SiCGe layer. The upper portion of the base is the undoped layer.

In an embodiment of the manufacturing method of the present invention, the undoped layer includes an undoped polysilicon layer.

Based on the above, in the present invention, the diffusion barrier layer is disposed between the base and the emitter, and the diffusion barrier layer has a characteristic of reducing the depth that the dopant in the emitter reaches into the underlaying layer, so the thickness of the base can be effectively reduced, and thus the formation time of the base can be effectively reduced.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIGS. 1A to 1C are schematic cross-sectional views of a manufacturing process of a transistor according to the first embodiment of the present invention.

FIGS. 2A to 2C are schematic cross-sectional views of a manufacturing process of a transistor according to the second embodiment of the invention.

### DESCRIPTION OF THE EMBODIMENTS

The embodiments are described in detail below with reference to the accompanying drawings, but the embodiments are not intended to limit the scope of the present invention. In addition, the drawings are for illustrative purposes only and are not drawn to the original dimensions. For the sake of easy understanding, the same elements in the following description will be denoted by the same reference numerals.

In addition, the terms mentioned in the text, such as “comprising”, “including” and “having” are all open-ended terms, i.e., meaning “including but not limited to”.

In addition, the directional terms mentioned in the text, such as “on” and “under”, are merely used to refer to the drawings and are not intended to limit the present invention.

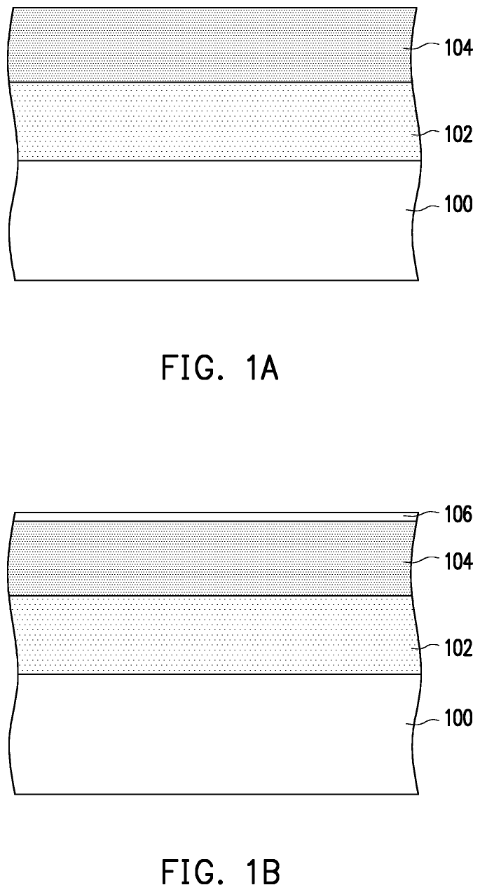

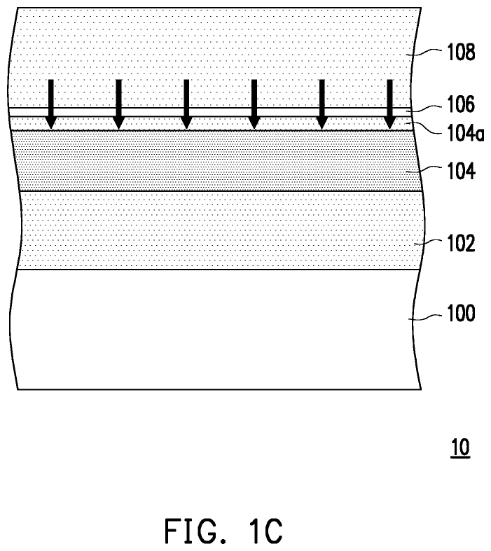

FIGS. 1A to 1C are schematic cross-sectional views of a manufacturing process of a transistor according to the first embodiment of the present invention. In the present embodiment, the first conductive type is N-type and the second conductive type is P-type, but the invention is not limited thereto. In other embodiments, the first conductive type may be P-type and the second conductive type may be N-type. In addition, in the present embodiment, the formed transistor is an HBT which mainly includes a collector, a base, an emitter and a diffusion barrier layer, which will be described in detail below.

Referring to FIG. 1A, a substitute 100 is provided. The substrate 100 is, for example, silicon substrate. In the present embodiment, the substrate 100 may be of a second conductive type (P-type) silicon substrate. Next, a collector layer 102 is formed on the substrate 100. The collector layer 102 is used to form the collector of the transistor of the present embodiment. In the present embodiment, the collector is of, for example, first conductive type (N type). In the present embodiment, the collector layer 102 is, for example, a silicon layer. The forming method of the collector layer 102 is, for example, an epitaxial growth process, and the first conductive-type dopant is in-situ doped during the formation process of the collector layer 102. After that, a base layer 104 is formed on the collector layer 102. The base layer 104 is used to form the base of the transistor of the present embodiment. In the present embodiment, the base is of, for example, second conductive type (P type). In the present embodiment, the base layer 104 is, for example, a SiGe layer. The forming method of the base layer 104 is, for example, a chemical vapor deposition (CVD) process, and the second conductive-type dopant is in-situ doped during the formation process of the base layer 104.

Referring to FIG. 1B, a diffusion barrier layer 106 is formed on the base layer 104. In the present embodiment, the diffusion barrier layer 106 is, for example, a silicon nitride layer.

The forming method of the diffusion barrier layer 106 is, for example, a CVD process. The diffusion barrier layer 106 has a characteristic of reducing the depth that the dopant (for example, the dopant in a layer subsequently formed on the diffusion barrier layer 106) penetrates through the diffusion barrier layer 106 and reaches into an underlaying layer. The above “reducing the depth that the dopant penetrates through and reaches into an underlaying layer” means that the depth that the dopant reaches into the underlaying layer is reduced compared to the case without the diffusion barrier layer 106. In the present embodiment, the thickness of the diffusion barrier layer 106 is, for example, between 5 Å and 10 Å, preferably between 5 Å and 7 Å. When the thickness of the diffusion barrier layer 106 exceeds 10 Å, only a very small amount of the dopant can be allowed penetrating through the diffusion barrier layer 106, and even do not allow the dopant penetrating through the diffusion barrier layer 106. When the thickness of the diffusion barrier layer 106 is less than 5 Å, the depth that the dopant reaches into a layer under the diffusion barrier layer 106 cannot be effectively reduced.

Referring to FIG. 1C, an emitter layer 108 is formed on the diffusion barrier layer 106 to complete the manufacture of the transistor 10 of the present embodiment. The emitter layer 108 is used to form the emitter of the transistor of the present embodiment. In the present embodiment, the emitter is of, for example, the first conductive type (N type). In general, the emitter layer 108 is a layer with a high doping concentration, which means that the doping concentration thereof is generally higher than that of the collector layer 102 and the base layer 104. In the present embodiment, the forming method of the emitter layer 108 is, for example, a CVD process, and the first conductive-type dopant is in-situ doped during the formation process of the emitter layer 108.

In the process of forming the emitter layer 108, the dopant in the emitter layer 108 may diffuse to the outside and into the base layer 104 below. In addition, after the transistor 10 is formed, in the subsequent thermal process, the dopant in the emitter layer 108 may also diffuse to the outside and into the base layer 104 below. In the present embodiment, since the diffusion barrier layer 106 is formed on the base layer 104 and the diffusion barrier layer 106 has a characteristic of reducing the depth that the dopant reaches into the base layer 104, the dopant in the emitter layer 108 can be diffused into only the upper portion of the base layer 104. At this time, the conductive type of the upper portion of the base layer 104 may be changed to the first conductive type (N type) from the second conductive type (P type) to form the doped layer 104a.

In the present embodiment, the diffusion barrier layer 106 can prevent the base layer 104 from changing to the first conductive type (N type) entirely due to the dopant in the emitter layer 108. On the other hand, since the diffusion barrier layer 106 allows the dopant in the emitter layer 108 diffusing into only the upper portion of the base layer 104, it is not necessary to form the base layer 104 with a larger thickness, that is, the thickness of the base layer 104 may be reduced compared to the case without the diffusion barrier layer 106. In this way, the overall thickness of the transistor 10 of the present embodiment may be effectively reduced, and the formation time of the base layer 104 may be effectively reduced.

In the transistor 10 of the present embodiment, the base is a single layer (base layer 104), but the invention is not limited thereto. In other embodiments, the base may also have a composite structure composed of multiple layers.

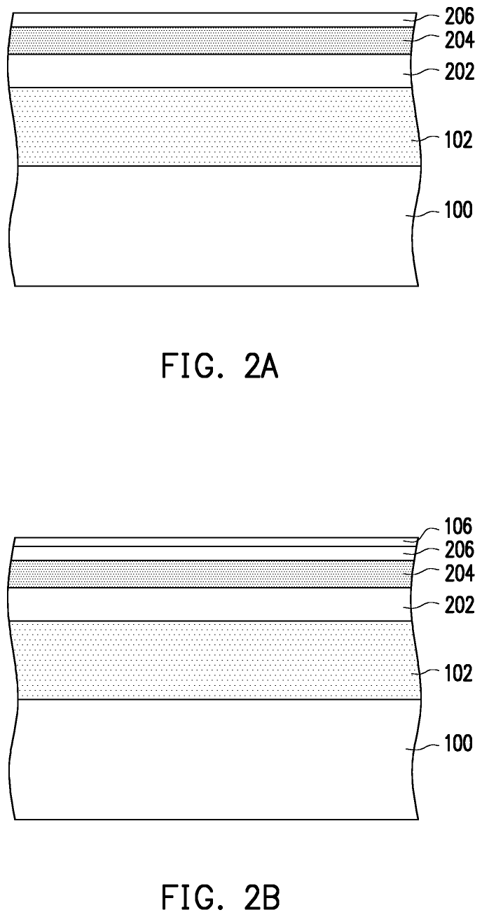

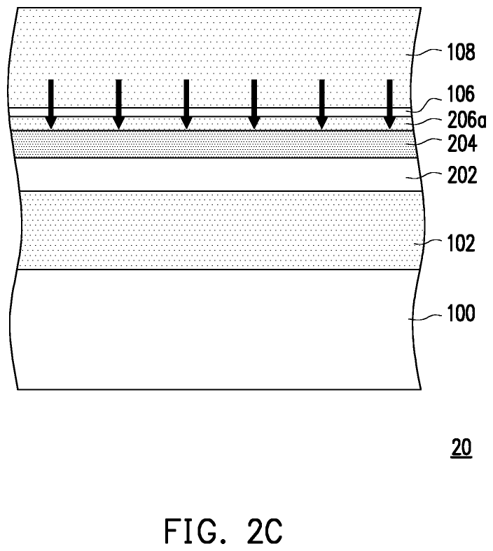

FIGS. 2A to 2C are schematic cross-sectional views of a manufacturing process of a transistor according to the second embodiment of the invention. In the present embodiment, the same elements as those of the first embodiment will be denoted by the same reference numerals and will not be described again.

Referring to FIG. 2A, a substitute 100 is provided. In the present embodiment, the substrate 100 is of, for example, a second conductive type (P type). Next, a collector layer 102 is formed on the substrate 100. The collector layer 102 is used to form the collector of the transistor of the present embodiment. In the present embodiment, the collector is of, for example, a first conductive type (N type). Then, a SiGe layer 202 is formed on the collector layer 102. In the present embodiment, the forming method of the SiGe layer 202 is, for example, a CVD process. Next, a doped SiCGe layer 204 is formed on the SiGe layer 202. In the present embodiment, the doped SiCGe layer 204 is of, for example, the second conductive type (P type). In the present embodiment, the forming method of the doped SiCGe layer 204 is, for example, a CVD process, and the second conductive-type dopant is in-situ doped during the formation process of the SiCGe layer 204. After that, an undoped layer 206 is formed on the doped SiCGe layer 204. The undoped layer 206 is, for example, an undoped polysilicon layer. In the present embodiment, the forming method of the undoped layer 206 is, for example, a CVD process. In the present embodiment, the SiGe layer 202, the doped SiGe layer 204 and the undoped layer 206 are used to form the base of the transistor of the present embodiment.

Referring to FIG. 2B, a diffusion barrier layer 106 is formed on the undoped layer 206. In the present embodiment, the diffusion barrier layer 106 is, for example, a silicon nitride layer. In the present embodiment, the forming method of the diffusion barrier layer 106 is, for example, a CVD process. The diffusion barrier layer 106 has a characteristic of reducing the depth that the dopant penetrates through the diffusion barrier layer 106 and reaches into a underlying layer. In the present embodiment, the thickness of the diffusion barrier layer 106 is, for example, between 5 Å and 10 Å, preferably between 5 Å and 7 Å. When the thickness of the diffusion barrier layer 106 exceeds 10 Å, only a very small amount of dopant may be allowed penetrating through the diffusion barrier layer 106, and even do not allow the dopant penetrating through the diffusion barrier layer 106. When the thickness of the diffusion barrier layer 106 is less than 5 Å, the depth that the dopant reaches into the underlying layer cannot be effectively reduced.

Referring to FIG. 2C, an emitter layer 108 is formed on the diffusion barrier layer 106 to complete the manufacture of the transistor 20 of the present embodiment. The emitter layer 108 is used to form the emitter of the transistor of the present embodiment. In the present embodiment, the emitter is of, for example, the first conductive type (N type). In general, the emitter layer 108 is a layer with a high doping concentration, which means that the doping concentration thereof is generally higher than that of the collector layer 102 and the base (the doped SiCGe layer 204). In the present embodiment, the forming method of the emitter layer 108 is, for example, a CVD process, and the first conductive-type dopant is in-situ doped during the formation process of the emitter layer 108.

During the formation of the emitter layer 108, the dopant in the emitter layer 108 may diffuse to the outside and into the undoped layer 206 below. In addition, after the transistor 20 is formed, in the subsequent thermal process, the dopant in the emitter layer 108 may also diffuse to the outside and into the undoped layer 206 below. In the present embodiment, since the diffusion barrier layer 106 is formed on the undoped layer 206 and the diffusion barrier layer 106 has a characteristic of reducing the depth that the dopant reaches into a layer under the diffusion barrier layer 106, the dopant in the emitter layer 108 may be diffused into only the undoped layer 206. At this time, undoped layer 206 may be changed to an undoped layer 206a with the first conductive type (N type).

In the present embodiment, since the diffusion barrier layer 106 allows the dopant in the emitter layer 108 diffusing into only the undoped layer 206, the undoped layer 206 may be completely changed to the doped layer 206a by controlling the thickness of the undoped layer 206. In addition, since the diffusion barrier layer 106 has the characteristic of reducing the depth that the dopant reaches into a layer under the diffusion barrier layer 106, it is not necessary to form the undoped layer 206 with a large thickness to avoid the dopant penetrating through the undoped layer 206. In this way, the overall thickness of the transistor 20 of the present embodiment can be effectively reduced, and the forming time of the undoped layer 206 may be effectively reduced.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A transistor, comprising:
a substrate;
a collector, disposed on the substrate;
a base, disposed on the collector;
an emitter, disposed on the base; and
a diffusion barrier layer, disposed between the base and the emitter,
wherein an upper portion of the base comprises a doped layer, and the diffusion barrier layer is disposed on the doped layer, and
wherein the emitter, the doped layer and the collector are of a first conductive type, and the rest of the base is of a second conductive type.

2. The transistor of claim 1, wherein the diffusion barrier layer comprises a silicon nitride layer.

3. The transistor of claim 1, wherein a thickness of the diffusion barrier layer is between 5 Å and 10 Å.

4. The transistor of claim 1, wherein the base comprises:
a SiGe layer, disposed on the collector;
a doped SiCGe layer, disposed on the SiGe layer; and
the doped layer, disposed on the doped SiCGe layer.

5. The transistor of claim 4, wherein the doped layer is a doped polysilicon layer.

6. A manufacturing method of a transistor, comprising:
forming a collector on a substrate;
forming a base on the collector;
forming a diffusion barrier layer on the base; and
forming a doped emitter on the diffusion barrier layer, wherein the dopant in the doped emitter penetrates through the diffusion barrier layer and into an upper portion of the base, so that the upper portion of the base is formed to a doped layer,
wherein the doped emitter, the doped layer and the collector are of a first conductive type, and the base is of a second conductive type.

7. The manufacturing method of claim 6, wherein the diffusion barrier layer comprises a silicon nitride layer.

8. The manufacturing method of claim 6, wherein a thickness of the diffusion barrier layer is between 5 Å and 10 Å.

9. The manufacturing method of claim 6, wherein a forming method of the base comprises:
forming a SiGe layer on the collector;
forming a doped SiCGe layer on the SiGe layer; and
forming an undoped layer on the doped SiCGe layer,
wherein the upper portion of the base is the undoped layer.

10. The manufacturing method of claim 9, wherein the undoped layer comprises an undoped polysilicon layer.
